(19) United States
(12) Patent Application Publication
(10) Pub. No.: US 2010/0039133 A1
(43) Pub. Date: Feb. 18, 2010

(54) PROBE HEAD CONTROLLING MECHANISM FOR PROBE CARD ASSEMBLIES

(75) Inventors: Andrew Weston McFarland, San Ramon, CA (US); Brandon Liew, Tracy, CA (US); James M. Porter, JR., Oakland, CA (US); Kevin Youl Yasumura, San Ramon, CA (US)

Correspondence Address: FORMFACTOR, INC.;LEGAL DEPARTMENT, 7005 SOUTHFRONT ROAD, LIVERMORE, CA, 94551, US

(73) Assignee: FORMFACTOR, INC., Livermore, CA (US)

(21) Appl. No.: 12/191,083

(22) Filed: Aug. 13, 2008

(51) Int. Cl. G01R 1/073

(52) U.S. Cl. 324/758

(57) ABSTRACT

A probe card assembly includes a first probe head having contact elements disposed on a respective surface for forming electrical contacts with corresponding terminals of corresponding electronic devices, a second probe head having contact elements disposed on a respective surface for forming electrical contacts with corresponding terminals of corresponding electronic devices, and a controlling mechanism coupled to the first and second probe heads for controlling movement of the first and second probe heads in a first direction substantially parallel to the respective surfaces more than in a second direction substantially normal to the respective surfaces.

### BACKGROUND

A probe card assembly is an apparatus typically used in connection with a tester in testing electronic devices, which are often referred to as devices under test or DUTs. The probe card assembly can include a plurality of contact elements with electrical and mechanical characteristics capable of forming resilient and compliant pressure contacts with a plurality of terminals of the DUTs. The probe card assembly can also include a number of connectors adapted to be connected to the tester via one or more communication links. The probe card assembly can be embedded with interconnect structures connecting the connectors on one side and the contact elements on the other side. When the tester is connected to the probe card assembly and the contact elements of the assembly are brought in contact with the terminals of the DUTs, the tester can transmit testing signals to the DUTs, and receive resulting signals therefrom. The received resulting signals can be analyzed to determine whether any of the DUTs is defective.

The relative locations between the terminals of the DUTs and their corresponding contact elements of the probe card assembly may change during testing due to thermal conditions. For example, the DUTs may be heated or cooled during the testing process, which in turn changes the temperature of one or more components of the probe card assembly. Heating and cooling of the DUTs can result in expansion or contraction of the DUTs to be tested. Because the probe card assembly is typically built of layers of different materials, each having a different coefficient of thermal expansion and different thermal transfer rates, a thermal gradient can vary across those layers, causing the layers to expand or contract in different magnitudes. As a result, some of the contact elements attached to one of the layers can be damaged or moved away from their corresponding terminals of the DUTs, thereby breaking electrical contacts there between.

One of the techniques in addressing the undesired thermal movements of the probe card assembly concerns manipulating material properties of the components that make up the probe card assembly. This technique can be limited in its scope and accuracy in adjusting thermal movements as available material properties are discrete.

Another technique concerns manipulating geometries of the components of the probe card assembly. Such technique can compromise on performance of the probe card assembly because it can temper known-good designs of the components.

As such, there is a need for addressing the thermal movements of the probe card assembly.

### SUMMARY

Embodiments of the invention relate to a probe card assembly, which can include a first probe head having contact elements disposed on a respective surface for forming electrical contacts with corresponding terminals of electronic devices, a second probe head having contact elements disposed on a respective surface for forming electrical contacts with corresponding terminals of corresponding electronic devices, and a controlling mechanism coupled to the first and second probe heads for controlling movement of the first and second probe heads in a first direction substantially parallel to the respective surfaces more than in a second direction substantially normal to their respective surfaces.

Embodiments of the invention also relate to a controlling mechanism for probe card assemblies. The controlling mechanism can include a controlling member having one or more overpass members each of which is adapted to extend across a border line of two neighboring probe heads of a probe card assembly, and being adapted to receive a coupling element capable of mechanically coupling the controlling member to the probe heads via the overpass members, wherein when the controlling member is coupled to the probe heads, the controlling member is capable of controlling movement of the probe heads in a first direction substantially parallel to the respective surfaces more than in a second direction substantially normal to their respective surfaces.

Embodiments of the invention also relate to a method for producing an electronic device. In the method, a probe card assembly having a first probe head having contact elements disposed on a respective surface, a second probe head having contact elements disposed on a respective surface, and a controlling mechanism coupled to the first and second probe heads for controlling movement of the first and second probe heads in a first direction substantially parallel to the respective surfaces more than in a second direction substantially normal to their respective surfaces can be provided. Electrical contacts can be formed between terminals of the electronic device with the respective contact elements of the first or second probe head. The electronic device can be tested with a tester via electrical paths there between established by the probe card assembly.

### BRIEF DESCRIPTION OF THE DRAWINGS

FIG. 1 illustrates a side view of a test system including a probe card assembly implemented with a probe head controlling mechanism in accordance with some embodiments of the invention.

FIG. 2 illustrates an exploded view of a probe head controlling mechanism and a number of probe heads in accordance with some embodiments of the invention.

FIG. 3 partially illustrates a cross-sectional view of a probe head controlling mechanism mechanically coupled to a probe head in accordance with some embodiments of the invention.

FIG. 4 illustrates a top view of a probe head controlling mechanism mechanically coupled to a number of probe heads in accordance with some embodiments of the invention.

FIG. 5 illustrates an exploded view of a probe head controlling mechanism and a number of probe heads in accordance with some embodiments of the invention.

FIG. 6 illustrates a top view of a probe head controlling mechanism mechanically coupled to a number of probe heads in accordance with some embodiments of the invention.

FIG. 7 illustrates a top view of a probe head controlling mechanism mechanically coupled to a number of probe heads in accordance with some embodiments of the invention.

### DETAILED DESCRIPTION OF EXEMPLARY EMBODIMENTS

This specification describes exemplary embodiments and applications of the invention. The invention, however, is not limited to these exemplary embodiments and applications or to the manner in which the exemplary embodiments and applications operate or are described herein. Moreover, the Figures may show simplified or partial views, and the dimensions of elements in the Figures may be exaggerated or otherwise not in proportion for clarity. In addition, as the terms “on” and “attached to” are used herein, one object (e.g., a material, a layer, a substrate, etc.) can be “on” or “attached to” another object regardless of whether the one object is directly on or attached to the other object or there are one or more intervening objects between the one object and the other object. Also, directions (e.g., above, below, top, bottom, side, up, down, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

Embodiments of the invention can relate to a controlling mechanism for controlling movements of components in a probe card assembly. The controlled components can include probe heads, which are typically substrates having contact elements extending from their respective surfaces for forming electrical contacts with corresponding terminals of DUTs. The controlling mechanism can control the movements of the probe heads in a direction substantially parallel to the respective surfaces of the probe heads more than in a direction substantially normal to the surfaces of same. As a result, in some embodiments of the invention, the controlling mechanism can reduce the soak time of the probe heads, which pertains to the time required for the probe heads to reach spatial stability, in the direction substantially parallel to the surfaces thereof. In some embodiments of the invention, the controlling mechanism can be configured to be more compliant in the direction substantially normal to the surfaces of the probe heads than in the direction parallel to the same. Thus, the controlling mechanism can deflect in the normal direction as necessary when adjusting the planarity of the probe heads, which in turn results in a desired planarity of the probe heads (and thus contact elements). Having a desired planarity of the contact elements facilitates establishing electrical contacts between the contact elements and the terminals of the DUTs. In some embodiments of the invention, the controlling mechanism can be configured to alter the effective coefficient of thermal expansion of the probe heads in order to control thermal movements thereof without changing known-good material choices for the probe heads. As a result, design variables introduced by adding the controlling mechanism to the probe card assembly can be limited.

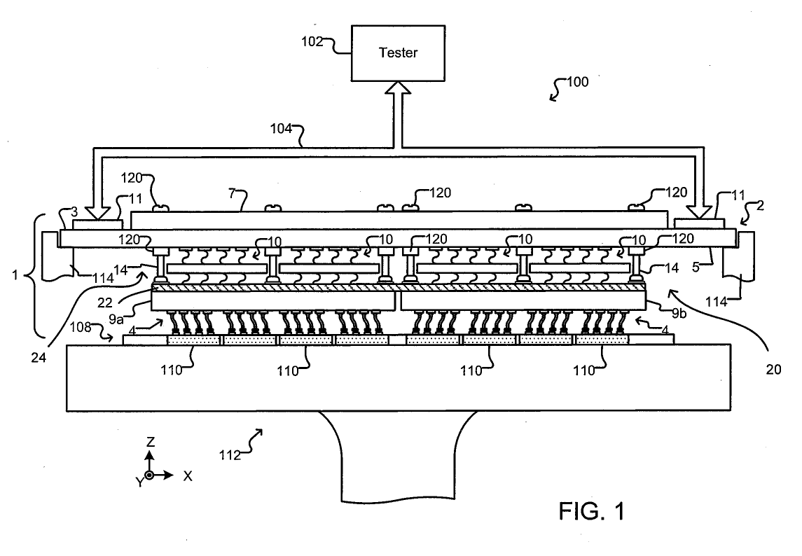

FIG. 1 illustrates a side view of a test system 100 including a probe card assembly 1 implemented with a probe head controlling mechanism 20 in accordance with some embodiments of the invention. The test system 100 can include a tester 102, a plurality of communication links 104, a probe card assembly 1, and a chuck (or stage) 112 for supporting and moving a plurality of DUTs 110. Although eight DUTs 110 are shown, more or less can be tested. Also, although the DUTs 110 are illustrated in FIG. 1 as semiconductor dies of a semiconductor wafer 108, the DUTs 110 can alternatively be other types of electronic devices. Examples of the DUTs 110 include any type of electronic device that is to be tested, including without limitation one or more dies of an unsingulated semiconductor wafer 108 (as shown in FIG. 1), one or more semiconductor dies singulated from a wafer (packaged or unpackaged), an array of singulated semiconductor dies (packaged or unpackaged) disposed in a carrier or other holding device, one or more multi-die electronics modules, one or more printed circuit boards, or any other type of electronic device or devices.

The tester 102 can include a computer or computers and/or other electronic elements configured to control testing of the DUTs 110. The communication links 104 can provide electrical communication paths between the tester 102 and the probe card assembly 1. The communication links 104 can comprise any media over which electronic, optical, or other types of signals can be communicated. Non-limiting examples include coaxial cables, fiber optic links, wireless transmitters/receives, drivers, receivers, etc. or any combination of the foregoing. Power, ground, and testing signals for testing the DUTs 110 can be provided to the DUTs 110 from the tester 102 through the communication links 104 and the probe card assembly 1. Resulting signals generated by the DUTs 110 can be provided to the tester 102 through the probe card assembly 1 and the communication links 104.

The probe card assembly 1 can include a wiring substrate 2. Electrical connectors 11 adapted to be connected with the communication links 104 can be disposed on an upper surface 3 of the wiring substrate 2. The probe card assembly 1 can also include contact elements 4, which can be configured to be pressed against and thus make electrical contacts with the terminals of the DUTs 110. The probe card assembly 1 can include electrically conductive interconnect structures (not shown) from the electrical connectors 11 to a lower surface 5 of the wiring substrate 2. The interconnect structures (not shown) between the electrical connectors 11 and the lower surface 5 of the wiring substrate 2 can comprise electrically conductive traces, vias, and/or terminals (not shown) on and/or in the wiring substrate 2. As will be discussed in more detail below, the contact elements 4 can be electrically connected to the electrical connectors 11 via probe heads 9a and 9b (only two are shown in the figure even though there can be more), interposers 10, and interconnect structures (not shown) in the wiring substrate 2. The probe card assembly 1 can thus provide electrical paths between the electrical connectors 11 and the contact elements 4. The probe card assembly 1 can thus provide an electrical interface between the communication links 104 and the terminals of the DUTs 110.

The contact elements 4 can be any type of electrically conductive probe, including without limitation needle probes, buckling beam probes, bump probes, or spring probes. The contact elements 4 can be resilient, conductive structures. Regardless of the probe type, the probe tip can be in a shape of a pyramid, truncated pyramid, triangle, blade, bump, or any other shapes suitable for forming electrical contacts with the terminals of the DUTs.

The test system 100 can test the DUTs 110, for example, as follows. As shown in FIG. 1, the DUTs 110 can be placed on the chuck 112, which can be moveable, and the probe card assembly 1 can be attached (e.g., bolted, clamped, etc.) to a mounting structure 114 associated with a housing or other apparatus (not shown) in which the chuck 112 is disposed. The chuck 112 can move the terminals of the DUTs 110 into contact with the contact elements 4 as shown in FIG. 1. Alternatively or additionally, the probe card assembly 1 can be moved to effect electrical contacts between the terminals of the DUTs 110 and the contact elements 4. The tester 102 can generate testing signals, which can be provided through the communication links 104 and the probe card assembly 1 to the DUTs 110. Resulting signals generated by the DUTs 110 in response to the testing signals can be provided through the probe card assembly 1 and the communication links 104 back to the tester 102, which can evaluate the resulting signals and determine whether the resulting signals are as expected and, consequently, whether the DUTs 110 passed the testing.

The wiring substrate 2 can comprise any substrates suitable for supporting electrical connectors 11 and enclosing interconnect structures therein. For example, the wiring substrate 2 can comprise a printed circuit board. The electrical connectors 11 can comprise any electrical connectors suitable for making electrical connections with the communication links 104. For example, the electrical connectors 11 can comprise pogo pin pads, zero-insertion-force (ZIF) connectors, etc.

A stiffener 7 can be configured to assist in resisting movement, warping, bending, etc. generally in a direction normal to the surface 3 of the wiring substrate 2 during testing of the DUTs 110 caused by, for example, changes in ambient temperature, temperature gradients, mechanical loads, etc. The stiffener 7 can comprise any rigid structure, such as a metal plate. A controlling mechanism 20 can be configured to control movements of the probe heads 9a and 9b in a direction substantially parallel to the respective surfaces thereof. The controlling mechanism 20 can comprise at least one controlling member 22 and a number of coupling elements 24 for mechanically coupling the controlling member 22 to the probe heads 9a and 9b, and the probe heads 9a and 9b to the stiffener 7. The coupling elements 24 can comprise a plurality of extension elements 14, which can fasten the controlling member 22 to the probe heads 9a and 9b. According to some embodiments of the invention, the extension elements 14 can be threaded on the outside, extend upwardly from the controlling member 22, and engage threaded fasteners 120 that extend from the stiffener 7 through holes (not shown) in the stiffener 7 and the wiring substrate 2. The coupling elements 24 can, for example, comprise differential screw assemblies. It is sufficient that the coupling element 24 couple the controlling member 22 to the probe heads 9a and 9b.

The coupling elements 24 can have functions in addition to coupling the probe heads 9a, and 9b to the controlling member 22 and the stiffener 7. For example, the coupling elements 24 can be configured to selectively adjust an orientation of the respective surfaces of the probe heads 9a and 9b to which the contact elements 4 are attached. For example, the coupling elements 24 can be configured to apply selectively push or pull forces to various locations on the probe heads 9a and 9b, thereby selectively altering the planarity (e.g., an orientation) of the probe heads 9a and 9b with respect to the stiffener 7 and/or the wiring substrate 2. This selective adjustment can occur during the manufacturing or assembly process of the probe card assembly, or after. Accordingly, the adjustment of the planarity of the probe heads can be maintained whether or not the contact elements are in contact with the electronic devices. In some embodiments, the capability of the controlling mechanism 20 to be more compliant, and in some instances, substantially more compliant, in the direction substantially normal to the surfaces of the probe heads than in the direction parallel to the probe heads can permit control of the thermal movement of the probe heads 9a, 9b, 9c and 9d in a parallel direction while not substantially affecting a capability to adjust the orientation of the probe head surfaces.

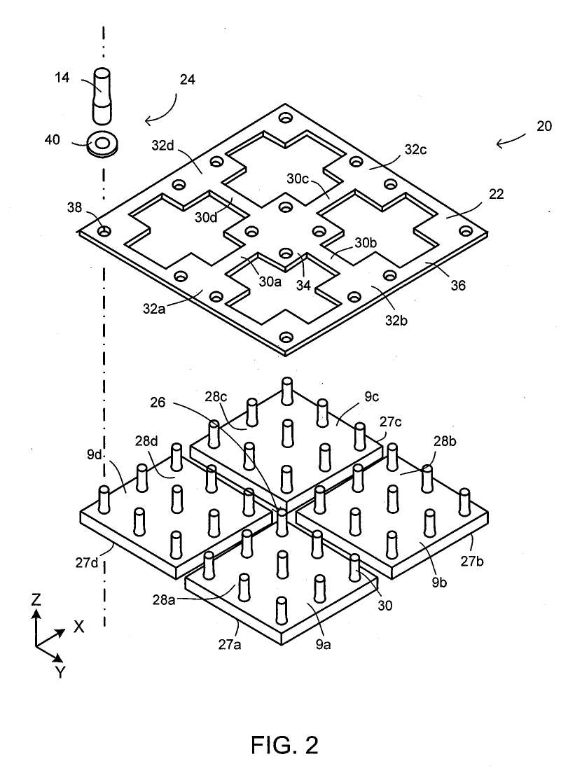

FIG. 2 illustrates an exploded view of the probe head controlling mechanism 20 and a number of probe heads 9a, 9b, 9c and 9d in accordance with some embodiments of the invention. As better shown in this drawing than FIG. 1, four probe heads 9a, 9b, 9c, and 9d can be arranged in alignment with each other about a reference point 26 at the neighboring corners of the respective probe heads 9a, 9b, 9c, and 9d. In the embodiments of the invention illustrated in FIG. 2, the probe heads 9a, 9b, 9c and 9d can be configured in square shapes in similar or identical sizes. In some other embodiments of the invention, the number of the probe heads can be more or less than four, and the probe heads can be configured in shapes other than squares, such as triangles, rectangles, parallelogram, regular polygons, irregular polygons, and other suitable shapes.

The probes heads 9a, 9b, 9c and 9d can be made of rigid materials capable of supporting electrical conducive structures embedded therein or constructed thereon. Examples of such materials can include ceramic, silicon, and other suitable materials. The probe heads 9a, 9b, 9c and 9d can have a plurality of contact elements (not shown in the figure) extending from bottom surfaces 27a, 27b, 27c, and 27d that are capable of forming resilient yet compliant pressure contacts with the terminals of the DUTs (not shown in the figure). The probe heads 9a, 9b, 9c and 9d can also include a number of studs 30 extending from their respective top surfaces 28a, 28b, 28c, and 28d of the probe heads 9a, 9b, 9c and 9d. The studs 30 can be attached to the probe heads 9a, 9b, 9c and 9d by means of, for example, soldering, adhesives, brazing, welding, and other suitable methods. The studs 30 can be threaded on the outside to match other threaded portions of other components of the probe card assembly. The numbers of studs 30 for each probe head 9a, 9b, 9c or 9d can be the same or different. In the embodiments of the invention illustrated in FIG. 2, each of the probe heads 9a, 9b, 9c, and 9d can include nine studs 30 symmetrically disposed on its respective surface 28a, 28b, 28c, and 28d in an evenly spaced apart configuration. In some other embodiments of the invention, the number of the studs 30 for each probe head 9a, 9b, 9c or 9d can be more or less than nine, and the studs 30 can be disposed in a asymmetric or irregular configuration.

The controlling mechanism 20 can include a controlling member 22 and one or more coupling elements 24 (only one is shown in the figure as an example) for mechanically coupling the controlling member 22 to the probe heads 9a, 9b, 9c and 9d. In the embodiments of the invention illustrated in FIG. 2, the controlling member 22 can include a number of arms 30a, 30b, 30c and 30d, each of which in its longitudinal direction (i.e., the direction of longer length than width) extends in parallel to a border line between any two neighboring ones of the probe heads 9a, 9b, 9c and 9d. The controlling member 22 can also include a number of overpass members 32a, 32b, 32c and 32d each of which extends across a border line of any two neighboring ones of the probe heads 9a, 9b, 9c and 9d. The controlling member 22 can also include a hub 34 connecting the arms 30a, 30b, 30c and 30d in alignment with the reference point 26 at the neighboring corners of the probe heads 9a, 9b, 9c and 9d. The controlling member 22 can further include a frame 36 connecting the arms 30a, 30b, 30c and 30d at their distal ends with respect to the hub 34. The frame 36 can be configured to be in alignment with at least one of the edges of the probe heads 9a, 9b, 9c and 9d.

The shape of the controlling member 22 can be modified in order to match various possible configurations of probe heads. In the embodiments of the invention illustrated in FIG. 2, the probe heads 9a, 9b, 9c and 9d can be configured in square shapes in similar or identical sizes. In some other embodiments of the invention, the number of the probe heads can be more or less than four, and the probe heads can be configured in shapes other than squares, such as triangles, rectangles, parallelogram, regular polygons, irregular polygons, and other suitable shapes. The controlling member 22 can be configured accordingly.

The controlling member 22 can have a number of openings 38 disposed on the overpass members 32a, 32b, 32c and 32d, as well as the hub 34. Each of the openings 38 can be configured in alignment with a respective stud 30 on the probe heads 9a, 9b, 9c and 9d. Each of the openings 38 can have a diameter sufficiently large to allow its respective stud 30 to pass through such that the controlling member 22 can be placed on top of the probe heads 9a, 9b, 9c and 9d.

In the embodiments of the invention illustrated in FIG. 2, the number of the openings 38 and the number of the studs 30 are identical. However, this does not always have to be the case. In some other embodiments of the invention, the number of the openings 38 can be greater than the number of the studs 30. Additional openings that do not match any studs can be selectively formed to alter the structural strength and thermal conductivity of the controlling member 36.

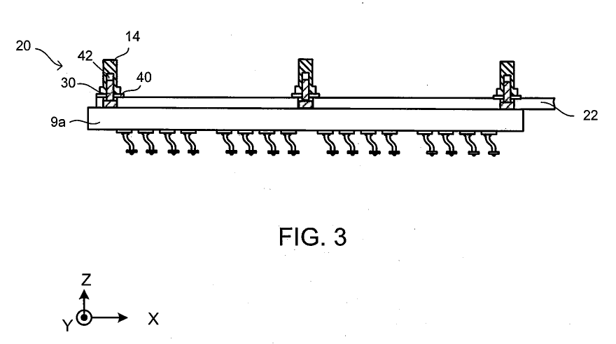

In the embodiments of the invention illustrated in FIG. 2, the coupling elements 24 can include multiple sets of extension elements 14 and washers 40, even though only one set is shown for clarity in FIG. 2. Each set of the extension element 14 and the washer 40 can be used to couple the controlling member 22 to the probe heads 9a, 9b, 9c and 9d. The mechanism of using the extension element 14 and washer 40 to couple the controlling member 22 with the probe heads 9a, 9b, 9c and 9d can be better appreciated in view of FIG. 3, which partially illustrates a cross-sectional view of the controlling mechanism 20 and the probe head 9a in accordance with some embodiments of the invention. Each of the extension elements 14 can have a hollow internal portion 42 having an inner diameter matching an outer diameter of its respective stud 30, and a length longer than that of the matching portion of the stud 30. The hollow inner portion 42 of the extension element 14 can be threaded to match the threaded portion of the stud 30 on the outside, such that the extension element 14 can be screwed onto the stud 30 and fastened the controlling member 22 to the probe head 9a. The washer 40 can be placed between the extension element 14 and the stud 30 to distribute the load thereof onto the controlling member 22. As such, the controlling member 22 can be restrained in relation to the probe head 9a.

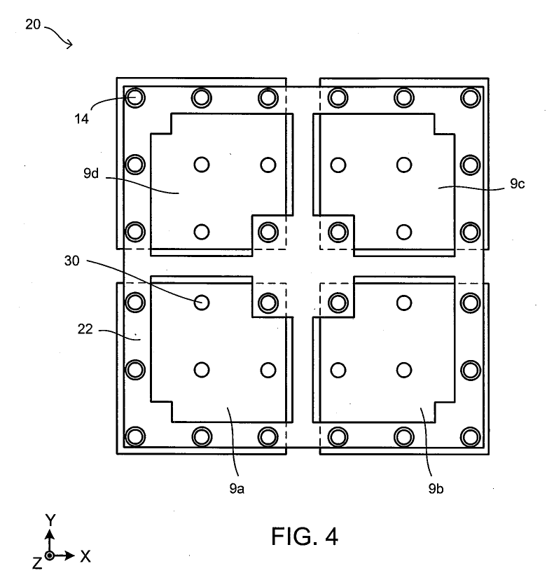

FIG. 4 illustrates a top view of the controlling mechanism 20 coupled to the probe heads 9a, 9b, 9c and 9d in accordance with some embodiments of the invention. The containing member 22 can be configured to be stiffer in a direction substantially parallel to the surfaces of the probe heads 9a, 9b, 9c and 9d (shown as the xy direction in the figure) than in a direction substantially normal to the surfaces of the probe heads 9a, 9b, 9c and 9d (shown as the z direction in the figure). Thus, the controlling mechanism 20 coupled to the probe heads 9a, 9b, 9c and 9d can control movements of the probe heads 9a, 9b, 9c and 9d in the direction substantially parallel to their respective surfaces greater than deflection of the probe heads 9a, 9b, 9c and 9d in the direction substantially normal to the respective surfaces.

Controlling undesired movements of the probe heads 9a, 9b, 9c and 9d can be beneficial for the probe card assembly 1 to effectively test the DUTs 110. Undesired movements of the probe cards 9a, 9b, 9c, and 9d can be induced by a change of ambient temperature, a thermal gradient across the probe card assembly 1, and mechanical loads onto the probe heads 9a, 9b, 9c and 9d. Those movements can significantly alter the positions of the contacts elements 4 in the direction substantially parallel to the surfaces of the probe heads 9a, 9b, 9c and 9d, which in turn can break the electrical contacts between the contact elements 4 and their corresponding terminals of the DUTs 110. As a result, the probe card assembly 1 can become ineffective in testing the DUTs.

The controlling mechanism 20 can control movements of the individual probe heads 9a, 9b, 9c and 9d, as well as relative movements among them in a direction substantially parallel to the respective surfaces of the probe heads 9a, 9b, 9c and 9d. For example, the controlling member 22 can be made of materials having a coefficient of thermal expansion smaller than that of the probe heads 9a, 9b, 9c and 9d. As an ambient temperature increases, the controlling member 22, and therefore the controlling mechanism 20 as a whole, can be less susceptible to thermal movements than the probe heads 9a, 9b, 9c and 9d in the direction substantially parallel to the respective surfaces thereof, thereby constraining the probe heads 9a, 9b, 9c and 9d in the parallel direction. In another example, the controlling member 22 can be made of materials having a coefficient of thermal expansion greater than that of the probe heads 9a, 9b, 9c and 9d. As an ambient temperature increases, the controlling member 22, and therefore the controlling mechanism 20 as a whole, can be more susceptible to thermal movements than the probe heads 9a, 9b, 9c and 9d in the direction substantially parallel to the respective surfaces thereof, thereby stretching the probe heads 9a, 9b, 9c and 9d in the parallel direction. Moreover, the controlling mechanism 20 can keep the center of the centroids of the probe heads 9a, 9b, 9c and 9d substantially stationary with respect to the centroids as an ambient temperature changes. By linking the probe heads 9a, 9b, 9c and 9d together, the controlling mechanism 20 can couple together individual movements of the probe heads 9a, 9b, 9c and 9d in the direction substantially parallel to their respective surfaces, thereby rendering the probe heads 9a, 9b, 9c and 9d to move in a coherent manner.

When the probe card assembly 1 implemented with the controlling mechanism 20 is being used to test the DUTs, the soak time required for the probe heads 9a, 9b, 9c and 9d to reach spatial stability can be reduced, compared to the probe heads without the controlling mechanism 20 or its equivalent alternatives. Altering the configurations and properties, such as coefficients of thermal expansion, of the controlling mechanism 20 can adjust the soak time in to order to meet various requirements of testing conditions.

One benefit of a reduced soak time of probe card assemblies can be an improved throughput of DUTs. Test temperature recalibration is necessary during installation of probe card assemblies, wafer exchanges, lot changes and maintenance of probe card assemblies. The soak times required for the probe card assemblies to reach spatial stability during the test temperature recalibration can amount to hundreds of lost productivity hours each day. Thus, the shorter the soak times of the probe card assemblies, the higher the throughput of the DUTs. The extension elements 14 and the studs 30 can be mechanically coupled to components of the probe card assembly 1 to allow for adjustment of planarity of the probe heads 9a, 9b, 9c and 9, while maintaining the adjustment whether or not the contact elements are in contact with the DUTs. As shown in FIG. 1, the extension elements 14 can be coupled to the stiffener 7 via their respective threaded fasteners 120. Although not shown in the side view of the probe card assembly 1 illustrated in FIG. 1, the studs 30 can also be directly coupled to the stiffener 7 via devices such as the threaded fasteners 120. By adjusting the threaded fasteners 120, a distance between each point where a stud 30 is attached to its respective probe head 9a, 9b, 9c or 9d and the stiffener 7 can be altered. According to the embodiments of the invention illustrated in FIG. 4, since there are nine attachment points on each probe head 9a, 9b, 9c or 9d, the planarity thereof with respect to the stiffener 7 can be adjusted by tuning their respective threaded fasteners 120.

The controlling mechanism 20 facilitates planarity adjustment of the probe heads 9a, 9b, 9c and 9d. The controlling member 22 can be configured to be stiffer in the direction substantially parallel to the respective surfaces of the probe heads 9a, 9b, 9c and 9d than in the direction substantially normal to the same, such that the controlling member 22 can deflect as necessary in the normal direction when the planarity of the probe heads 9a, 9b, 9c and 9d is being adjusted. Moreover, the controlling mechanism 20 can reduce bending moments generated by the extension elements 120 coupled with the shear stresses induced by movements of the probe heads 9a, 9b, 9c and 9d in the direction substantially parallel to their respective surfaces. This helps keep the surfaces of the probe heads 9a, 9b, 9c and 9d planar.

Maintaining a desired planarity of the probe heads 9a, 9b, 9c and 9d can be important for the probe card assembly 1 to be effective in testing the DUTs. As discussed above, the contact elements 4 of the probe card assembly 1 need to be precisely positioned in order to form desired electrical contacts with the terminals of the DUTs. The probe heads 9a, 9b, 9c and 9d should be planar in a manner that the tips of the contact elements 4 form a plane matching the surface of the semiconductor wafer 108 containing the DUTs 110. In some cases where the surface of the semiconductor wafer 108 is not planar, the tips of the contact elements 4 can be configured to match the contour of the semiconductor wafer 108 in a non-planar fashion. In some embodiments of the invention, each individual contact element 4 can have a compliant characteristic to provide desired design tolerance in matching the tips of the contact elements 4 with the surface of the semiconductor wafer 108 that can account for, for example, variances in manufacturing tolerances of the wafer, the contact elements, or others, and in some instances provide for some limited thermal motion in a vertical direction within the range of the contact resilience yet still maintain electrical and pressure contact with the DUT. Since the controlling mechanism 20 can facilitate the adjustment of planarity of the probe heads 9a, 9b, 9c and 9d, it can improve the effectiveness of the probe card assembly 1 in testing the DUTs 110.

In addition, the controlling mechanism 20 can simplify the structure and configuration in designing and fabricating planarity adjustment mechanisms. Conventionally, the planarity adjustment mechanisms need to adjust not only the planarity of the probe heads, but also their lateral movements. In the embodiments of the invention, since the controlling mechanism 20 serves the function of controlling movements of the probe heads 9a, 9b, 9c and 9d in the direction substantially parallel to their respective surfaces, the structures and configurations of the planarity adjustment mechanisms can be designed without the lateral controlling function, and therefore simplifying their fabrication.

The controlling mechanism 20 can also allow for independent assembly of the probe heads 9a, 9b, 9c and 9d to the controlling member 22. This feature can simplify repair and replacement of the probe heads 9a, 9b, 9c and 9d, which can be translated into saved time and improved throughput of the DUTs. For example, the controlling member 22 can be removed in field by decoupling the extension element 14, such that a defective probe head can be replaced with a replacement probe head. In some embodiments, the force applied by the extension element 14 to the controlling member 22 can also be adjusted in field by loosening or tightening the element 14. This can lead to a shorter down time of the probe card assembly 1.

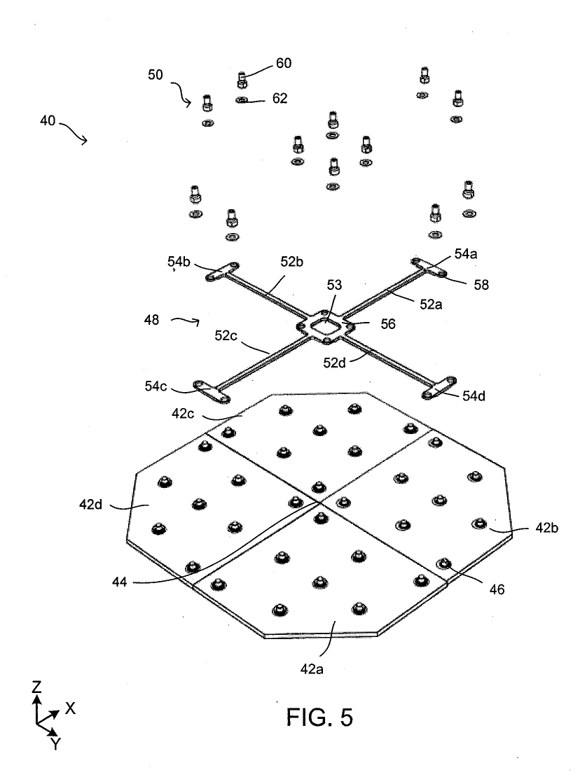

FIG. 5 illustrates an exploded view of a controlling mechanism 40 and a number of probe heads 42a, 42b, 42c and 42d in accordance with some embodiments of the invention. The probe heads 42a, 42b, 42c, and 42d can be arranged in alignment with each other about a reference point 44 at their respective neighboring center corners. In the embodiments of the invention illustrated in FIG. 4, the probe heads 42a, 42b, 42c and 42d can be configured in pentagon shapes in similar or identical sizes. The probes heads 42a, 42b, 42c and 42d can be made of materials capable of maintaining proper planarity and supporting electrical conducive structures embedded therein or constructed thereon. Examples of such materials can include ceramic, silicon, and other suitable materials. The probe heads 42a, 42b, 42c and 42d can have a plurality of contact elements (not shown in the figure). The probe heads 42a, 42b, 42c and 42d can also include a number of studs 46 extending from their respective surfaces for coupling the probe heads 42a, 42b, 42c and 42d to other components, such as a stiffener, of the probe card assembly. The studs 46 can be attached to the probe heads 42a, 42b, 42c and 42d by means of soldering, adhesives, brazing, welding, and other suitable methods. The studs 46 can be threaded on the outside to match other threaded portions of other components. The numbers of the studs 46 for each probe head 42a, 42b, 42c or 42d can be the same or different.

The controlling mechanism 40 can include a controlling member 48 and a plurality of coupling elements 50 for mechanically coupling the controlling member 48 to the probe heads 42a, 42b, 42c and 42d. The controlling member 48 can include a number of arms 52a, 52b, 52c and 52d, each of which in its longitudinal direction extends in parallel to a border line between any two neighboring ones of the probe heads 42a, 42b, 42c and 42d. The controlling member 48 can also include a number of overpass members 54a, 54b, 54c and 54d each of which extends across a border line of two neighboring ones of the probe heads 42a, 42b, 42c and 42d. The controlling member 48 can also include a hub 56 connecting the arms 52a, 52b, 52c and 52d in alignment with the reference point 44 at the center neighboring corners of the probe heads 42a, 42b, 42c and 42d. The hub 56 can have an opening 53 in the center for adjusting the structural strength of the controlling member 48. For example, increasing the size of the opening 53 can render the controlling member 48 more compliant in the direction normal to the surfaces of the probe heads 42a, 42b, 42c and 42d.

The controlling member 48 can have a number of openings 58 disposed on the overpass members 54a, 54b, 54c and 54d, as well as the hub 56. Each of the openings 58 can be configured in alignment with its respective stud 46 on the probe heads 42a, 42b, 42c and 42d. Each of the openings 58 can have a diameter sufficiently large to allow its respective stud 46 to pass through such that the controlling member 48 can be placed on top of the probe heads 42a, 42b, 42c and 42d, but not so large that the probe heads 42a, 42b, 42c and 42d can appreciably move relative to controlling member 48.

In the embodiments of the invention illustrated in FIG. 5, the number of the openings 58 and the number of the studs 46 are identical. However, this does not always have to be the case. In some other embodiments of the invention, the number of the openings 58 can be greater than the number of the studs 46. Additional openings that do not match any studs can be selectively formed to alter the structural strength and thermal conductivity of the controlling member 48.

The coupling elements 50 can include multiple sets of extension elements 60 and washers 62. Each set of the extension element 60 and the washer 62 can be used to couple the controlling member 48 to the probe heads 42a, 42b, 42c and 42d. The mechanism of using the extension elements 60 and the washers 62 to couple the controlling member 48 with the probe heads 42a, 42b, 42c and 42d can be similar to those described above with reference to FIG. 3.

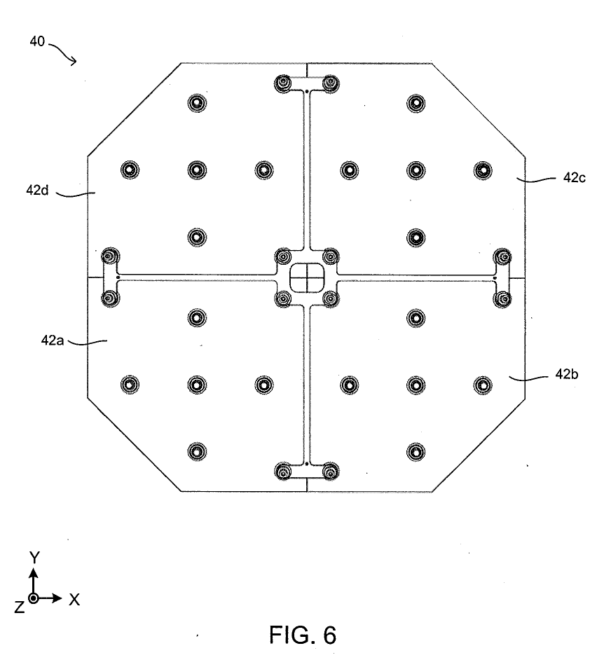

FIG. 6 illustrates a top view of the controlling mechanism 40 coupled to the probe heads 42a, 42b, 42c and 42d in accordance with some embodiments of the invention. As described above, the controlling mechanism 40 can control movements of the probe heads 42a, 42b, 42c and 42d in the direction substantially parallel to their respective surfaces greater than deflection thereof in the direction substantially normal to the same. The controlling mechanism 40 can also be configured to be less susceptible to thermal movement than the probe heads 42a, 42b, 42c and 42d in the direction substantially parallel to the surface thereof. As discussed above, the controlling mechanism 40 can reduce the soak time of the probe heads 42a, 42b, 42c and 42d in the direction substantially parallel to their respective surfaces, facilitate adjustment of planarity thereof, simplify the configuration and fabrication of the planarity adjustment mechanisms, and allow for independent assembly of the probe heads.

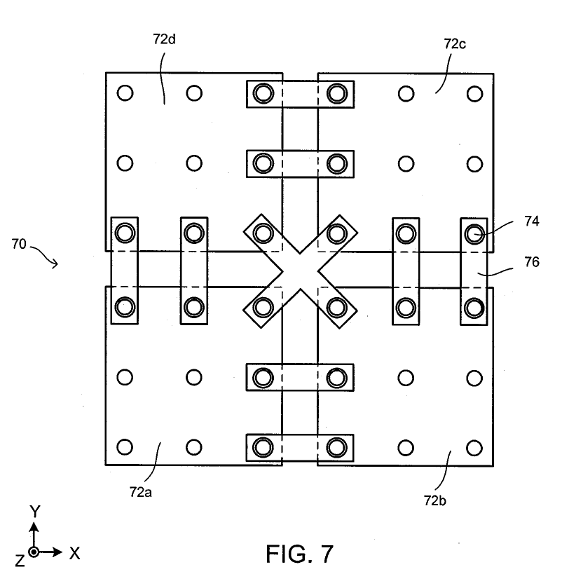

FIG. 7 illustrates a top view of a controlling mechanism 70 coupled to probe heads 72a, 72b, 72c and 72d in accordance with some embodiments of the invention. The controlling mechanism 70 can be similar to the controlling mechanisms described above in the sense, for example, that it also includes one or more coupling elements 74 that couple one or more controlling members 76 to the probe heads 72a, 72b, 72c and 72d. The controlling mechanism 70 can be different from the controlling mechanisms described above in the sense, for example, that the controlling members 76 can be include in a number of separate pieces of overpass members across border lines between two neighboring ones of the probe heads 72a, 72b, 72c and 72d. As described above, the controlling mechanism 70 can control movements of the probe heads 72a, 72b, 72c and 72d in the direction substantially parallel to their respective surfaces greater than deflection thereof in the direction substantially normal to the same. The controlling mechanism 70 can also be configured to be less susceptible to thermal expansion than the probe heads 72a, 72b, 72c and 72d in the direction substantially parallel to the surface thereof. In some embodiments of the invention, different materials of the individual pieces of the controlling member 76 can be selected to allow for uniform motion of the probe head centroids when non-uniform thermal fields exist in the probe card assembly 1. As discussed above, the controlling mechanism can reduce the soak time of the probe heads 72a, 72b, 72c and 72d in the direction substantially parallel to the surfaces of the probe heads, facilitate adjustment of planarity thereof, simplify the configuration and fabrication of the planarity adjustment mechanisms, and allow for independent assembly of the probe heads.

In some embodiments of the invention, the controlling members 76 can be active elements, such as actuators, that can push and pull the probe heads 72a, 72b, 72c and 72d to their respective positions, and control them in the direction substantially parallel to the surfaces of the probe heads 72a, 72b, 72c and 72d once they are positioned. One or more sensors (not shown in the figure) can be implemented in the probe card assembly to determine positions of the probe heads 72a, 72b, 72c and 72d. One or more controllers (not shown in the figure) can be implemented in the probe card assembly to control the actuators in response to a feedback signal indicating the positions of the probe heads 72a, 72b, 72c and 72d from the sensors. As described above, the active elements can control movements of the probe heads 72a, 72b, 72c and 72d in the direction substantially parallel to their respective surfaces greater than deflection thereof in the direction substantially normal to the same. They can also be configured to be less susceptible to thermal movement than the probe heads 72a, 72b, 72c and 72d in the direction substantially parallel to the surfaces thereof. As discussed above, they can reduce the soak time of the probe heads 72a, 72b, 72c and 72d in the direction substantially parallel to the surfaces of the probe heads, facilitate adjustment of planarity thereof, simplify the configuration and fabrication of the planarity adjustment mechanisms, and allow for independent assembly of the probe heads.

It is noted that although the coupling element in FIG. 2-7 is illustrated as including an extension element and a washer, it can be designed in various other configurations. For example, the washer can be an optional component. In some embodiments of the invention, the coupling element can be configured to couple the controlling member to the probe heads using various mechanisms. For example, the coupling element can be a clutch that couples the controlling member to the probe heads by friction. Press fitting mechanism can also be used to couple the controlling member to the probe heads. Pins, rivets, clamps, keys into key ways, magnets, adhesives, soldering, brazing, welding, other suitable means and a combination thereof may be used to couple the controlling member to the probe heads in other embodiments of the invention. It is sufficient that the coupling mechanism couple the controlling member to the probe heads.

Although specific embodiments and applications of the invention have been described in this specification, there is no intention that the invention be limited these exemplary embodiments and applications or to the manner in which the exemplary embodiments and applications operate or are described herein. Any equivalent structures capable of controlling movements of probe heads in the manners described above fall in the spirit and scope of the invention. For example, the controlling member can take many shapes and/or in many pieces, and be a passive or active component. The coupling element can be any mechanisms as described above or their equivalents suitable for coupling the controlling member to the probe heads.

We claim:

1. A probe card assembly comprising:
a first probe head having contact elements disposed on a respective surface for forming electrical contacts with corresponding terminals of corresponding electronic devices;
a second probe head having contact elements disposed on a respective surface for forming electrical contacts with corresponding terminals of corresponding electronic devices; and
a controlling mechanism coupled to the first and second probe heads for controlling movement of the first and second probe heads in a first direction substantially parallel to the respective surfaces more than in a second direction substantially normal to the respective surfaces.

2. The probe card assembly of claim 1 further comprising:
a third probe head having contact elements disposed on a respective surface for forming electrical contacts with corresponding terminals of corresponding electronic devices;
a fourth probe head having contact elements disposed on a respective surface for forming electrical contacts with corresponding terminals of corresponding electronic devices,
wherein a respective center of the centroids of the first, second, third and fourth probe heads remains substantially stationary with respect to the centroids as an ambient temperature changes.

3. The probe card assembly of claim 1 wherein the constraining mechanism is more compliant in the second direction than in the first direction for allowing for adjustment of planarity of the first and second probe heads and maintaining the adjustment whether or not the contact elements are in contact with the electronic devices.

4. The probe card assembly of claim 1 wherein the controlling mechanism comprises a controlling member, and a coupling element for coupling the controlling member to the first and second probe heads.

5. The probe card assembly of claim 4 wherein the controlling member comprises one or more arms each of which in its longitudinal direction extends parallel to a border line of the first and second probe heads.

6. The probe card assembly of claim 4 wherein the controlling member comprises one or more overpass members each of which extends across a border line of the first and second probe heads.

7. The probe card assembly of claim 6 wherein the controlling member comprises a hub connecting the arms.

8. The probe card assembly of claim 7 wherein the controlling member comprises a frame connecting the arms at their distal ends with respect to the hub.

9. The probe card assembly of claim 4 wherein the coupling element comprises at least one extension element, such that the extension element is adapted to restrain the controlling member in relation to the first and second probe heads.

10. The probe card assembly of claim 9 wherein the extension element is adapted to be mechanically coupled to a component of the probe card assembly other than the first and second probe heads that is less compliant in the first direction than in the second direction.

11. The probe card assembly of claim 1 wherein the controlling mechanism comprises an actuator capable of actively controlling the first and second probe heads.

12. The probe card assembly of claim 11 wherein the controlling mechanism comprises a sensor for detecting respective positions of the first and second probe heads and generating a feedback signal indicating the positions to control the actuator.

13. A controlling mechanism for probe card assemblies comprising:
a controlling member having one or more overpass members each of which is adapted to extend across a border line of two neighboring probe heads of a probe card assembly, and being adapted to receive a coupling element capable of mechanically coupling the controlling member to the probe heads via the overpass members,
wherein when the controlling member is coupled to the probe heads, the controlling member is capable of controlling movement of the probe heads in a first direction substantially parallel to respective surfaces of the probe heads more than in a second direction substantially normal to the respective surfaces.

14. The controlling mechanism of claim 13 is more compliant in the second direction than in the first direction for allowing for adjustment of planarity of the probe heads.

15. The controlling mechanism of claim 13 wherein the controlling member comprises one or more arms each of which in its longitudinal direction extends parallel to a border line of the probe heads.

16. The controlling mechanism of claim 15 wherein the controlling member comprises a hub connecting the arms.

17. The controlling mechanism of claim 16 wherein the controlling member comprises a frame connecting the arms at their distal ends with respect to the hub.

18. A method for producing an electronic device comprising:
providing a probe card assembly comprising:
a first probe head having contact elements disposed on a respective surface;
a second probe head having contact elements disposed on a respective surface; and
a controlling mechanism coupled to the first and second probe heads for controlling movement of the first and second probe heads in a first direction substantially parallel to the respective surfaces more than in a second direction substantially normal to the respective surfaces;
forming electrical contacts between terminals of the electronic device with the respective contact elements of the first or second probe head; and
testing the electronic device via electrical paths there between established by the probe card assembly.

19. The method of claim 18 further comprising:
adjusting a planarity of at least one of the first and second probe heads.
